(19) United States
(12) Patent Application Publication
(10) Pub. No.: US 2011/0193066 A1
(43) Pub. Date: Aug. 11, 2011

(54) CURRENT LIMITING ELEMENT FOR PIXELS IN ELECTRONIC DEVICES

(75) Inventors: Ian D. Parker, Santa Barbara, CA (US); Johann Thomas Trujillo, Goleta, CA (US); Nigel Morton Coe, Santa Barbara, CA (US)

(73) Assignee: E. I. DU PONT DE NEMOURS AND COMPANY, WILMINGTON, DE (US)

(21) Appl. No.: 12/854,456

(22) Filed: Aug. 11, 2010

Related U.S. Application Data
(60) Provisional application No. 61/233,597, filed on Aug. 13, 2009.

(51) Int. Cl. H01L 27/32

(52) U.S. Cl. 257/40; 257/E27.119

(57) ABSTRACT

An apparatus for pixellated radiation configured to prevent short-circuits from adversely impacting display quality. A current limiting element connects a pixel to a power bus to minimize effects of pixel failures. Failure of a single pixel will have minimum impact on perceived display quality, thus avoiding failure of an entire row or column which would be noticeable to an observer of the display.

### RELATED APPLICATION

This application claims priority under 35 U.S.C. §119(e) from Provisional Application Ser. No. 61/233,597 filed Aug. 13, 2009 which is incorporated by reference in its entirety.

### FIELD OF THE DISCLOSURE

This disclosure relates in general to an electronic device. In particular, it relates to an apparatus for pixellated radiation and current limiting element providing electrical connection between power source and pixel.

### BACKGROUND INFORMATION

Increasingly, active organic molecules are used in electronic devices. These active organic molecules have electronic or electro-radiative properties including electroluminescence. Electronic devices that incorporate organic active materials may be used to convert electrical energy into radiation and may include a light-emitting diode, light-emitting diode display, or diode laser.

Two methods are commonly used to prepare organic light-emitting diode (“OLED”) displays: vacuum deposition, and solution processing. (The latter includes all forms of applying the layers from a fluid, as a true solution or a suspension.) Vacuum deposition equipment typically has very high investment costs, and inferior material utilization (high operating costs), so solution processing is preferred, especially for large area displays.

Liquid processes for the deposition of organic active layers include any number of technologies for control of layer thickness on a substrate. Some of these technologies include self regulated methods to control thickness, including spin coating, rod coating, dip coating, roll coating, gravure coating or printing, lithographic or flexographic printing, screen coating or printing, etc. Other of these technologies seek to control deposition thickness using controlled deposition techniques including ink jet printing, spray coating, nozzle coating, slot die coating, curtain coating, bar or slide coating, etc.

The liquid processing is used to form discrete pixel areas comprising several layers, including organic active material. These pixels can be a single pixel, or composed of two or more sub-pixels, for example, red, green and blue sub-pixels can be used to form a single pixel in a display application. These pixels are typically connected directly to a power bus to provide a voltage potential across the pixel and resultant luminescence. In a direct parallel electrical connection, the failure of one pixel can produce a short-circuit resulting in large current flows to the short-circuit and resultant lowering of voltage to adjacent pixels. This voltage reduction can result in a column or row of dark pixels, a noticeable degradation to a user of the display, and can render the display non-functional. Prior solutions to this problem include the use of thicker films to reduce the likelihood of short-circuits, or connection of pixels in a series arrangement. Inconsistent operation of pixels typically leads to poor device performance and poor yield in device fabricating processes.

There continues to be a need for improved devices for mitigating pixel failures in display and lamp applications.

### SUMMARY

In one embodiment, an electronic device comprises a power bus, a first conductive element which can function as an anode or a cathode and a second conductive element which can also function as either anode or cathode, a first organic active material and a first current limiting element, is described in more detail below. The first and second conductive elements and first organic active material form a first pixel, the first current limiting element forms an electrical connection between the power bus and the first pixel. The pixel can be a single illuminating area, or may be composed of two or more sub-pixels which in one embodiment can provide luminance in the red, green and blue spectrums to form the single pixel. A multitude of pixels can be connected to the power bus using one or more types of current limiting elements. Various materials can be used as current limiting elements, including organic and inorganic resistive materials, and two or more types of current limiting elements can be used in successive pixels connected to the power bus. In one embodiment the current limiting element can have a resistivity of 100 to 10,000 ohms.

The anode and cathode can be metal or non-metal materials, with one embodiment employing metal oxide for the anode. One possible choice of metal oxide is an indium tin oxide. In one embodiment, a serpentine pattern can be used in the indium tin oxide to provide the current limiting resistive connection between the pixel and the power bus. The electronic device can be an organic light emitting diode (OLED) used in display applications or in a general lighting capacity as a lamp.

In one embodiment, a substrate (such as glass) is useful as a base for the electronic device. The term “organic electronic device” or sometimes just “electronic device”, is intended to mean a device including one or more organic semiconductor layers or materials. An organic electronic device includes, but is not limited to: (1) a device that converts electrical energy into radiation (e.g., a light-emitting diode, light emitting diode display, diode laser, or lighting panel), (2) a device that detects a signal using an electronic process (e.g., a photodetector, a photoconductive cell, a photoresistor, a photoswitch, a phototransistor, a phototube, an infrared (“IR”) detector, or a biosensors), (3) a device that converts radiation into electrical energy (e.g., a photovoltaic device or solar cell), (4) a device that includes one or more electronic components that include one or more organic semiconductor layers (e.g., a transistor or diode), or any combination of devices in items (1) through (4).

### BRIEF DESCRIPTION OF THE FIGURES

FIG. 1 is an illustration of an electronic device,

FIG. 2 is an illustration of prior art direct connection of pixels to a power bus.

FIG. 3 is an illustration of the prior art current draw, and associated voltage drop, resulting from a short-circuit in at least one pixel in a series of pixels connected to the power bus.

FIG. 4 is an illustration of one embodiment where a serpentine pattern of ITO is used as the current limiting element to mitigate effects of a pixel short-circuit.

FIG. 5 is an illustration of one embodiment highlighting the isolation of a failed pixel, where adjacent pixels are unaffected by a single pixel failure.

### DETAILED DESCRIPTION

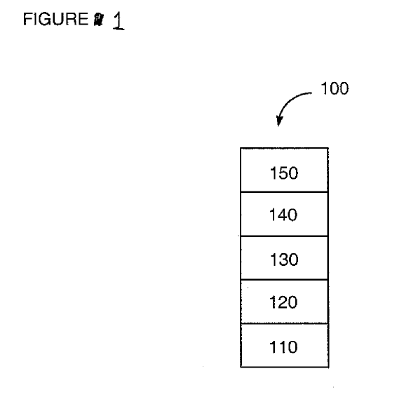

One example of an electronic device comprising an organic light-emitting diode (“OLED”), as shown in FIG. 1 and designated 100. The device has an anode layer 110, a buffer layer 120, a photoactive layer 130, and a cathode layer 150. Adjacent to the cathode layer 150 is an optional electron-injection/transport layer 140. Between the buffer layer 120 and the photoactive layer 130, is an optional hole-injection/transport layer (not shown).

As used herein, the term “buffer layer” or “buffer material” is intended to mean electrically conductive or semiconductive materials and may have one or more functions in an organic electronic device, including but not limited to, planarization of the underlying layer, charge transport and/or charge injection properties, scavenging of impurities such as oxygen or metal ions, and other aspects to facilitate or to improve the performance of the organic electronic device. Buffer materials may be polymers, oligomers, or small molecules, and may be in the form of solutions, dispersions, suspensions, emulsions, colloidal mixtures, or other compositions. The term “hole transport” when referring to a layer, material, member, or structure, is intended to mean such layer, material, member, or structure facilitates migration of positive charges through the thickness of such layer, material, member, or structure with relative efficiency and small loss of charge. The term “electron transport” when referring to a layer, material, member or structure, is intended to mean such a layer, material, member or structure that promotes or facilitates migration of negative charges through such a layer, material, member or structure into another layer, material, member or structure. The term “hole injection” when referring to a layer, material, member, or structure, is intended to mean such layer, material, member, or structure facilitates injection and migration of positive charges through the thickness of such layer, material, member, or structure with relative efficiency and small loss of charge. The term “electron injection” when referring to a layer, material, member, or structure, is intended to mean such layer, material, member, or structure facilitates injection and migration of negative charges through the thickness of such layer, material, member, or structure with relative efficiency and small loss of charge.

The device may include a support or substrate (not shown) that can be adjacent to the anode layer 110 or the cathode layer 150. Most frequently, the support is adjacent the anode layer 110. The support can be flexible or rigid, organic or inorganic. Generally, glass or flexible organic films are used as a support. The anode layer 110 is an electrode that is more efficient for injecting holes compared to the cathode layer 150. The anode can include materials containing a metal, mixed metal, alloy, metal oxide or mixed oxide. Suitable materials include the mixed oxides of the Group 2 elements (i.e., Be, Mg, Ca, Sr, Ba, Ra), the Group 11 elements, the elements in Groups 4, 5, and 6, and the Group 8-10 transition elements. If the anode layer 110 is to be light transmitting, mixed oxides of Groups 12, 13 and 14 elements, such as indium-tin-oxide, may be used. As used herein, the phrase “mixed oxide” refers to oxides having two or more different cations selected from the Group 2 elements or the Groups 12, 13, or 14 elements. Some non-limiting, specific examples of materials for anode layer 110 include, but are not limited to, indium-tin-oxide (“ITO”), aluminum-tin-oxide, gold, silver, copper, and nickel. The anode may also comprise an organic material such as polyaniline, polythiophene, or polypyrrole. The IUPAC number system is used throughout, where the groups from the Periodic Table are numbered from left to right as 1-18 (CRC Handbook of Chemistry and Physics, 81^{st} Edition, 2000).

In one embodiment, the buffer layer 120 comprises hole transport materials. Examples of hole transport materials for layer 120 have been summarized for example, in Kirk-Othmer Encyclopedia of Chemical Technology, Fourth Edition, Vol. 18, p. 837-860, 1996, by Y. Wang. Both hole transporting molecules and polymers can be used. Commonly used hole transporting molecules include, but are not limited to: 4,4′,4″-tris(N,N-diphenyl-amino)-triphenylamine (TDATA); 4,4′,4″-tris(N-3-methylphenyl-N-phenyl-amino)-triphenylamine (MTDATA); methylphenyl)-[1,1′-biphenyl]-4,4′-diamine (TPD); 1,1-bis[(di-4-tolylamino) phenyl]cyclohexane (TAPC); N,N′-bis(4-methylphenyl)-N,N′-bis(4-ethylphenyl)-[1,1′-(3,3′-dimethyl)biphenyl]-4,4′-diamine (ETPD); tetrakis-(3-methylphenyl)-N,N,N′,N′-2,5-phenylenediamine (FDA); α-phenyl-4-N,N-diphenylaminostyrene (TPS); p-(diethylamino)benzaldehyde diphenylhydrazone (DEH); triphenylamine (TPA); bis[4-(N,N-diethylamino)-2-methylphenyl](4-methylphenyl)methane (MPMP); 1-phenyl-3-[p-(diethylamino)styryl]-5-[p-(diethylamino)phenyl]pyrazoline (PPR or DEASP); 1,2-trans-bis(9H-carbazol-9-yl)cyclobutane (DCZB); N,N,N′,N′-tetrakis(4-methylphenyl)-(1,1′-biphenyl)-4,4′-diamine (TTB); N,N′-bis(naphthalen-1-yl)-N,N′-bis-(phenyl)benzidine (α-NPB); and porphyrinic compounds, such as copper phthalocyanine. Commonly used hole transporting polymers include, but are not limited to, poly(9,9,-dioctyl-fluorene-co-N-(4-butylphenyl)diphenylamine), and the like, polyvinylcarbazole, (phenylmethyl)polysilane, poly(dioxythiophenes), polyanilines, and polypyrroles. It is also possible to obtain hole transporting polymers by doping hole transporting molecules such as those mentioned above into polymers such as polystyrene and polycarbonate.

The photoactive layer 130 may typically be any organic electroluminescent (“EL”) material, including, but not limited to, small molecule organic fluorescent compounds, fluorescent and phosphorescent metal complexes, conjugated polymers, and mixtures thereof. Examples of fluorescent compounds include, but are not limited to, pyrene, perylene, rubrene, coumarin, derivatives thereof, and mixtures thereof. Examples of metal complexes include, but are not limited to, metal chelated oxinoid compounds, such as tris(8-hydroxyquinolato)aluminum (Alq3); cyclometalated iridium and platinum electroluminescent compounds, such as complexes of iridium with phenylpyridine, phenylquinoline, or phenylpyrimidine ligands as disclosed in Petrov et al., U.S. Pat. No. 6,670,645 and Published PCT Applications WO 03/063555 and WO 2004/016710, and organometallic complexes described in, for example, Published PCT Applications WO 03/008424, WO 03/091688, and WO 03/040257, and mixtures thereof. Electroluminescent emissive layers comprising a charge carrying host material and a metal complex have been described by Thompson et al., in U.S. Pat. No. 6,303,238, and by Burrows and Thompson in published PCT applications WO 00/70655 and WO 01/41512. Examples of conjugated polymers include, but are not limited to poly(phenylenevinylenes), polyfluorenes, poly(spirobifluorenes), polythiophenes, poly(p-phenylenes), copolymers thereof, and mixtures thereof.

The particular material chosen may depend on the specific application, potentials used during operation, or other factors. The EL layer 130 containing the electroluminescent organic material can be applied using any number of techniques including vapor deposition, solution processing techniques or thermal transfer. In another embodiment, an EL polymer precursor can be applied and then converted to the polymer, typically by heat or other source of external energy (e.g., visible light or UV radiation).

Optional layer 140 can function both to facilitate electron injection/transport, and can also serve as a confinement layer to prevent quenching reactions at layer interfaces. More specifically, layer 140 may promote electron mobility and reduce the likelihood of a quenching reaction if layers 130 and 150 would otherwise be in direct contact. Examples of materials for optional layer 140 include, but are not limited to, include metal chelated oxinoid compounds, such as tris(8-hydroxyquinolato)aluminum (Alq3), bis(2-methyl-8-quinolinolato)(para-phenyl-phenolato)aluminum(III) (BAlQ), and tetrakis-(8-hydroxyquinolinato)zirconium (IV) (ZrQ); and azole compounds such as 2-(4-biphenylyl)-5-(4-t-butylphenyl)-1,3,4-oxadiazole (PBD), 3-(4-biphenylyl)-4-phenyl-5-(4-t-butylphenyl)-1,2,4-triazole (TAZ), and 1,3,5-tri(phenyl-2-benzimidazole)benzene (TPBI); quinoxaline derivatives such as 2,3-bis(4-fluorophenyl)quinoxaline; phenanthrolines such as 4,7-diphenyl-1,10-phenanthroline (DPA) and 2,9-dimethyl-4,7-diphenyl-1,10-phenanthroline (DDPA); and mixtures thereof. Alternatively, optional layer 140 may be inorganic and comprise BaO, LiF, Li₂O, or the like.

The cathode layer 150 is an electrode that is particularly efficient for injecting electrons or negative charge carriers. The cathode layer 150 can be any metal or nonmetal having a lower work function than the first electrical contact layer (in this case, the anode layer 110). As used herein, the term “lower work function” is intended to mean a material having a work function no greater than about 4.4 eV. As used herein, “higher work function” is intended to mean a material having a work function of at least approximately 4.4 eV.

Materials for the cathode layer can be selected from alkali metals of Group 1 (e.g., Li, Na, K, Rb, Cs,), the Group 2 metals (e.g., Mg, Ca, Ba, or the like), the Group 12 metals, the lanthanides (e.g., Ce, Sm, Eu, or the like), and the actinides (e.g., Th, U, or the like). Materials such as aluminum, indium, yttrium, and combinations thereof, may also be used. Specific non-limiting examples of materials for the cathode layer 150 include, but are not limited to, barium, lithium, cerium, cesium, europium, rubidium, yttrium, magnesium, samarium, and alloys and combinations thereof.

In other embodiments, additional layer(s) may be present within organic electronic devices. For example, a layer (not shown) between the buffer layer 120 and the EL layer 130 may facilitate positive charge transport, band-gap matching of the layers, function as a protective layer, or the like. Similarly, additional layers (not shown) between the EL layer 130 and the cathode layer 150 may facilitate negative charge transport, band-gap matching between the layers, function as a protective layer, or the like. Layers that are known in the art can be used. In addition, any of the above-described layers can be made of two or more layers. Alternatively, some or all of inorganic anode layer 110, the buffer layer 120, the EL layer 130, and cathode layer 150, may be surface treated to increase charge carrier transport efficiency. The choice of materials for each of the component layers may be determined by balancing the goals of providing a device with high device efficiency with the cost of manufacturing, manufacturing complexities, or potentially other factors.

The different layers may have any suitable thickness. In one embodiment, inorganic anode layer 110 is usually no greater than approximately 500 nm, for example, approximately 10-200 nm; buffer layer 120, is usually no greater than approximately 250 nm, for example, approximately 50-200 nm; EL layer 130, is usually no greater than approximately 100 nm, for example, approximately 50-80 nm; optional layer 140 is usually no greater than approximately 100 nm, for example, approximately 20-80 nm; and cathode layer 150 is usually no greater than approximately 100 nm, for example, approximately 1-50 nm. If the anode layer 110 or the cathode layer 150 needs to transmit at least some light, the thickness of such layer may not exceed approximately 100 nm. In organic light emitting diodes (OLEDs), electrons and holes, injected from the cathode 150 and anode 110 layers, respectively, into the EL layer 130, form negative and positively charged polar ions in the polymer. These polar ions migrate under the influence of the applied electric field, forming a polar ion exciton with an oppositely charged species and subsequently undergoing radiative recombination. A sufficient potential difference between the anode and cathode, usually less than approximately 12 volts, and in many instances no greater than approximately 5 volts, may be applied to the device. The actual potential difference may depend on the use of the device in a larger electronic component. In many embodiments, the anode layer 110 is biased to a positive voltage and the cathode layer 150 is at substantially ground potential or zero volts during the operation of the electronic device. A battery or other power source(s) may be electrically connected to the electronic device as part of a circuit but is not illustrated in FIG. 1.

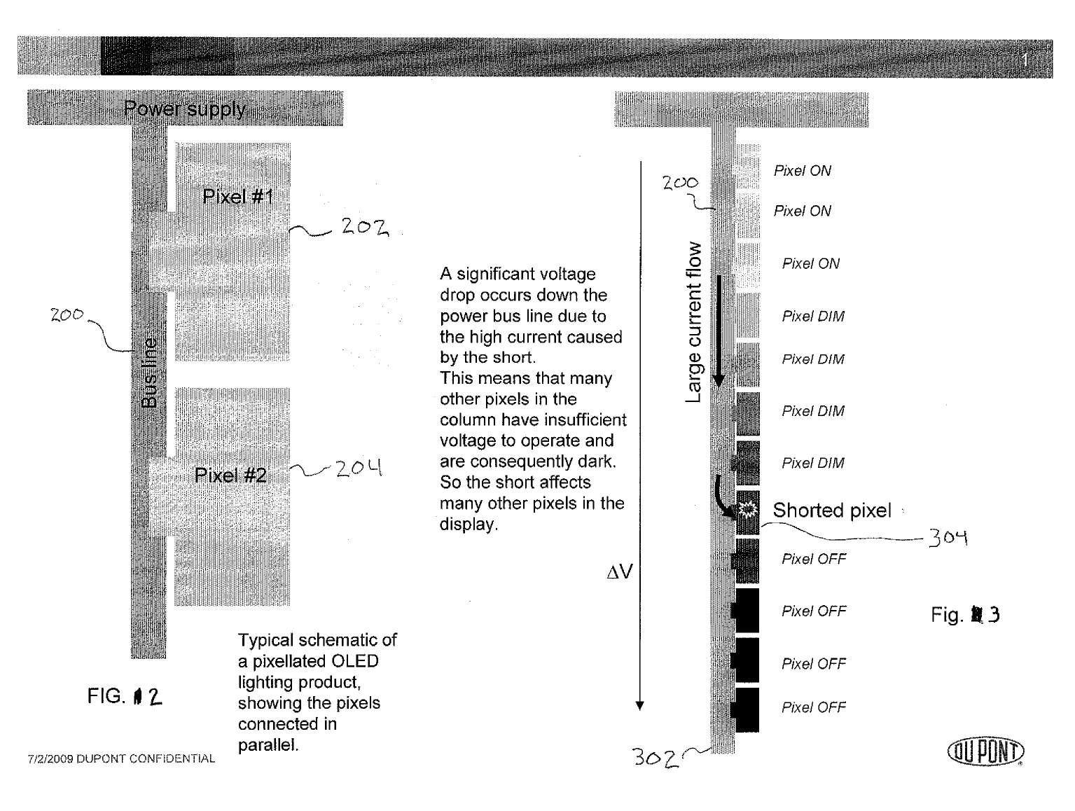

FIG. 2 illustrates the prior art where a power supply and bus line are referenced collectively as power bus 200, and pixel 202 and 204 are connected directly to the power bus 200. FIG. 2 thus provides a typical schematic of a pixellated OLED lighting product, showing the pixels connected in parallel.

FIG. 3 illustrates the operation of an arrangement of FIG. 2 when a failure produces a short-circuit in pixel 304. Current flows along the power bus with decreasing voltage levels toward the lower portion 302 of power bus 200. This voltage drop causes a dimming of the pixels prior to the shorted pixel 304, and non-operation of the pixels from after the shorted pixel 304 to the lower portion 302. The arrow with reference figures ΔV indicates a significant voltage drop occurs down the power bus line due to the high current caused by the short. The voltage drop results in insufficient voltage going to pixels in the column for the pixels to operate, causing the affected pixels to go dark, either dim or off (“Pixel DIM”), (“Pixel OFF”). Thus, one short in this type of display may affect many other pixels in the display.

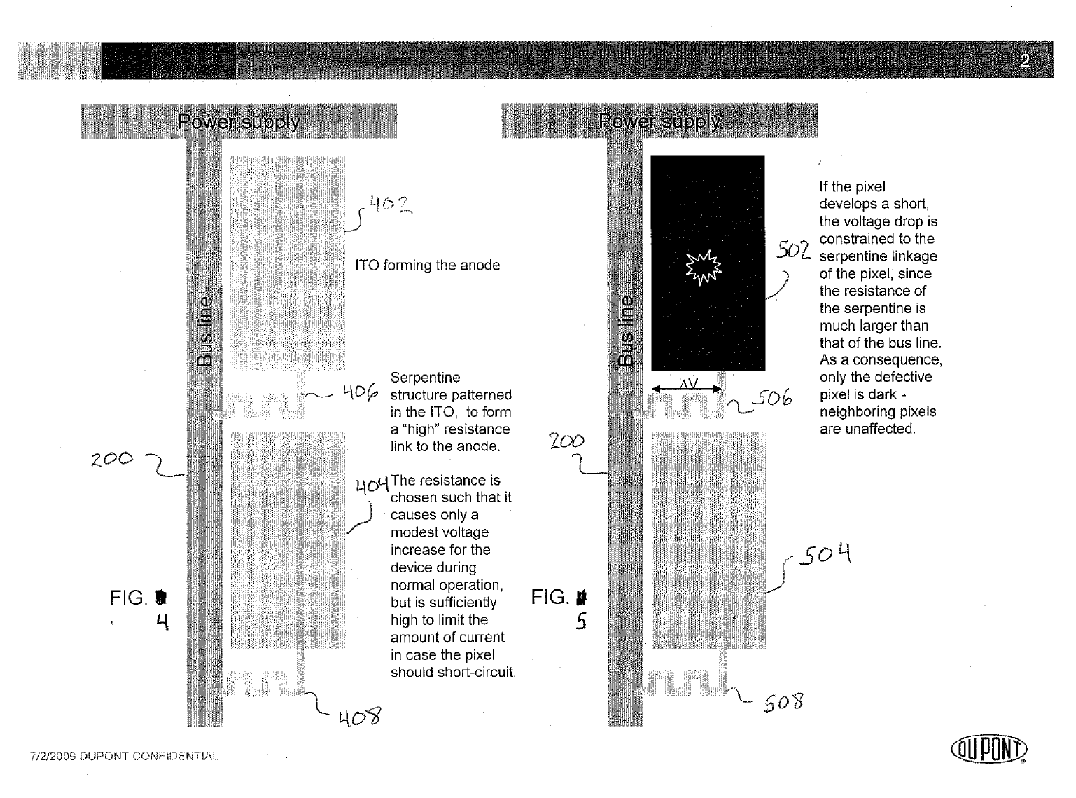

FIG. 4 illustrates one embodiment of the invention where pixel 402 is connected to power bus 200 via a first current limiting element 406. In one embodiment the first current limiting element 406 is a serpentine structure patterned in indium tin oxide (ITO), where the ITO forms a first conductive element. Pixel 404 can be connected to power bus 200 via a second current limiting element 408, and current limiting elements 406 and 408 may be the same or different. The serpentine structures for current limiting elements 406 and 408 patterned in the anode (e.g., ITO) form a “high” resistance link to the anode. In another embodiment the current limiting resistor can be of short and wide dimension. The design requirement for the current limiting resistor is to provide a resistance value that leads to only a small voltage increase in the pixel during normal operation, but is sufficiently high to limit the current level in case of a short-circuit in a pixel. The resistance can be controlled by selecting a material with appropriate resistivity and by adjusting the physical dimensions of the resistive element. For example, a low resistance material such as ITO can have a very high aspect ratio (length/width), while a high resistance material can have a short length and wide width. The resistive material can be selected from any number of materials, including metals, metal oxides and organic conductors.

FIG. 5 illustrates pixels 502 and 504 connected to power bus 200 via current limiting elements 506 and 508, respectively. If pixel 502 fails, resulting in a short-circuit, voltage drop is limited to the current limiting element 506, while pixel 504 and other pixels (not shown) retain sufficient voltage for operation. The resistance of the serpentine is much larger than that of the bus line. Hence, a pixel failure results in only an isolated dark pixel, while the remaining portions of the display or lamp including neighboring pixels remain illuminated.

For a radiation-emitting organic active layer, suitable radiation-emitting materials include one or more small molecule materials, one or more polymeric materials, or a combination thereof. A small molecule material may include any one or more of those described in, for example, U.S. Pat. No. 4,356,429 (“Tang”); U.S. Pat. No. 4,539,507 (“Van Slyke”); U.S. Patent Application Publication No. US 2002/0121638 (“Grushin”); or U.S. Pat. No. 6,459,199 (“Kido”). Alternatively, a polymeric material may include any one or more of those described in U.S. Pat. No. 5,247,190 (“Friend”); U.S. Pat. No. 5,408,109 (“Heeger”); or U.S. Pat. No. 5,317,169 (“Nakano”). An exemplary material is a semiconducting conjugated polymer. An example of such a polymer includes poly(paraphenylenevinylene) (PPV), a PPV copolymer, a polyfluorene, a polyphenylene, a polyacetylene, a polyalkylthiophene, poly(n-vinylcarbazole) (PVK), or the like. In one specific embodiment, a radiation-emitting active layer without any guest material may emit blue light.

For a radiation-responsive organic active layer, a suitable radiation-responsive material may include a conjugated polymer or an electroluminescent material. Such a material includes, for example, a conjugated polymer or an electro- and photo-luminescent material. A specific example includes poly(2-methoxy,5-(2-ethyl-hexyloxy)-1,4-phenylene vinylene) (“MEH-PPV”) or a MEH-PPV composite with CN-PPV.

For a hole-injecting layer, hole-transport layer, electron-blocking layer, or any combination thereof, a suitable material includes polyaniline (“PANI”), poly(3,4-ethylenedioxythiophene) (“PEDOT”), polypyrrole, an organic charge transfer compound, such as tetrathiafulvalene tetracyanoquinodimethane (“TTF-TCQN”), a hole-transport material as described in Kido, or any combination thereof.

For an electron-injecting layer, electron transport layer, hole-blocking layer, or any combination thereof, a suitable material includes a metal-chelated oxinoid compound (e.g., Alq₃ or aluminum(III)bis(2-methyl-8-quinolinato)4-phenylphenolate (“BAlq”)); a phenanthroline-based compound (e.g., 2,9-dimethyl-4,7-diphenyl-1,10-phenanthroline (“DDPA”) or 9,10-diphenylanthracene (“DPA”)); an azole compound (e.g., 2-tert-butylphenyl-5-biphenyl-1,3,4-oxadiazole (“PBD”) or 3-(4-biphenyl)-4-phenyl-5-(4-t-butylphenyl)-1,2,4-triazole (“TAZ”); an electron transport material as described in Kido; a diphenylanthracene derivative; a dinaphthylanthracene derivative; 4,4-bis(2,2-diphenyl-ethen-1-yl)-biphenyl (“DPVBI”); 9,10-di-beta-naphthylanthracene; 9,10-di-(naphthenyl)anthracene; 9,10-di-(2-naphthyl)anthracene (“ADN”); 4,4′-bis(carbazol-9-yl)biphenyl (“CBP”); 9,10-bis-[4-(2,2-diphenylvinyl)-phenyl]-anthracene (“BDPVPA”); anthracene, N-arylbenzimidazoles (such as “TPBI”); 1,4-bis[2-(9-ethyl-3-carbazoyl)vinylenyl]benzene; 4,4′-bis[2-(9-ethyl-3-carbazoyl)vinylenyl]-1,1′-biphenyl; 9,10-bis[2,2-(9,9-fluorenylene)vinylenyl]anthracene; 1,4-bis[2,2-(9,9-fluorenylene)vinylenyl]benzene; 4,4′-bis[2,2-(9,9-fluorenylene)vinylenyl]-1,1′-biphenyl; perylene, substituted perylenes; tetra-tert-butylperylene (“TBPe”); bis(3,5-difluoro-2-(2-pyridyl)phenyl-(2-carboxypyridyl) iridium III (“F(Ir)Plc”); a pyrene, a substituted pyrene; a styrylamine; a fluorinated phenylene; oxidiazole; 1,8-naphthalimide; a polyquinoline; one or more carbon nanotubes within PPV; or any combination thereof.

For an electronic component, such as a resistor, transistor, capacitor, etc., the organic layer may include one or more of thiophenes (e.g., polythiophene, poly(alkylthiophene), alkylthiophene, bis(dithienthiophene), alkylanthradithiophene, etc.), polyacetylene, pentacene, phthalocyanine, or any combination thereof.

Examples of an organic dye include 4-dicyanmethylene-2-methyl-6-(p-dimethylaminostyryl)-4H-pyran (DCM), coumarin, pyrene, perylene, rubrene, a derivative thereof, or any combination thereof.

Examples of an organometallic material include a functionalized polymer comprising one or more functional groups coordinated to at least one metal. An exemplary functional group contemplated for use includes a carboxylic acid, a carboxylic acid salt, a sulfonic acid group, a sulfonic acid salt, a group having an OH moiety, an amine, an imine, a amine, an N-oxide, a phosphine, a phosphine oxide, a β-dicarbonyl group, or any combination thereof. An exemplary metal contemplated for use includes a lanthanide metal (e.g., Eu, Tb), a Group 7 metal (e.g., R^{e}), a Group 8 metal (e.g., Ru, Os), a Group 9 metal (e.g., Rh, Ir), a Group 10 metal (e.g., Pd, Pt), a Group 11 metal (e.g., Au), a Group 12 metal (e.g., Zn), a Group 13 metal (e.g., Al), or any combination thereof. Such an organometallic material includes a metal chelated oxinoid compound, such as tris(8-hydroxyquinolato)aluminum (Alq₃); a cyclometalated iridium or platinum electroluminescent compound, such as a complex of iridium with phenylpyridine, phenylquinoline, or phenylpyrimidine ligands as disclosed in published PCT Application WO 02/02714, an organometallic complex described in, for example, published applications US 2001/0019782, EP 1191612, WO 02/15645, WO 02/31896, and EP 1191614; or any mixture thereof.

An examples of a conjugated polymer includes a poly(phenylenevinylene), a polyfluorene, a poly(spirobifluorene), a copolymer thereof, or any combination thereof.

Selecting a liquid medium can also be an important factor for achieving one or more proper characteristics of the liquid composition. A factor to be considered when choosing a liquid medium includes, for example, viscosity of the resulting solution, emulsion, suspension, or dispersion, molecular weight of a polymeric material, solids loading, type of liquid medium, boiling point of the liquid medium, temperature of an underlying substrate, thickness of an organic layer that receives a guest material, or any combination thereof.

In some embodiments, the liquid medium includes at least one solvent. An exemplary organic solvent includes a halogenated solvent, a hydrocarbon solvent, an aromatic hydrocarbon solvent, an ether solvent, a cyclic ether solvent, an alcohol solvent, a glycol solvent, a glycol ether solvent, an ester or diester solvent, a glycol ether ester solvent, a ketone solvent, a nitrile solvent, a sulfoxide solvent, an amide solvent, or any combination thereof.

An exemplary halogenated solvent includes carbon tetrachloride, methylene chloride, chloroform, tetrachloroethylene, chlorobenzene, bis(2-chloroethyl)ether, chloromethyl ethyl ether, chloromethyl methyl ether, 2-chloroethyl ethyl ether, 2-chloroethyl propyl ether, 2-chloroethyl methyl ether, or any combination thereof.

An exemplary colloidal-forming polymeric acid includes a fluorinated sulfonic acid (e.g., fluorinated alkylsulfonic acid, such as perfluorinated ethylenesulfonic add) or any combinations thereof.

An exemplary hydrocarbon solvent includes pentane, hexane, cyclohexane, heptane, octane, decahydronaphthalene, a petroleum ether, ligroine, or any combination thereof.

An exemplary aromatic hydrocarbon solvent includes benzene, naphthalene, toluene, xylene, ethyl benzene, cumene (iso-propyl benzene) mesitylene (trimethyl benzene), ethyl toluene, butyl benzene, cymene (iso-propyl toluene), diethylbenzene, iso-butyl benzene, tetramethyl benzene, sec-butyl benzene, tert-butyl benzene, anisole, 4-methylanisole, 3,4-dimethylanisole, or any combination thereof.

An exemplary ether solvent includes diethyl ether, ethyl propyl ether, dipropyl ether, diisopropyl ether, dibutyl ether, methyl t-butyl ether, glyme, diglyme, benzyl methyl ether, isochroman, 2-phenylethyl methyl ether, n-butyl ethyl ether, 1,2-diethoxyethane, sec-butyl ether, diisobutyl ether, ethyl n-propyl ether, ethyl isopropyl ether, n-hexyl methyl ether, n-butyl methyl ether, methyl n-propyl ether, or any combination thereof.

An exemplary cyclic ether solvent includes tetrahydrofuran, dioxane, tetrahydropyran, 4 methyl-1,3-dioxane, 4-phenyl-1,3-dioxane, 1,3-dioxolane, 2-methyl-1,3-dioxolane, 1,4-dioxane, 1,3-dioxane, 2,5-dimethoxytetrahydrofuran, 2,5-dimethoxy-2,5-dihydrofuran, or any combination thereof.

An exemplary alcohol solvent includes methanol, ethanol, 1-propanol, 2-propanol, 1-butanol, 2-butanol, 2-methyl-1-propanol (i.e., iso-butanol), 2-methyl-2-propanol (i.e., tert-butanol), 1-pentanol, 2-pentanol, 3-pentanol, 2,2-dimethyl-1-propanol, 1-hexanol, cyclopentanol, 3-methyl-1-butanol, 3-methyl-2-butanol, 2-methyl-1-butanol, 2,2-dimethyl-1-propanol, 3-hexanol, 2-hexanol, 4-methyl-2-pentanol, 2-methyl-1-pentanol, 2-ethylbutanol, 2,4-dimethyl-3-pentanol, 3-heptanol, 4-heptanol, 2-heptanol, 1-heptanol, 2-ethyl-1-hexanol, 2,6-dimethyl-4-heptanol, 2-methylcyclohexanol, 3-methylcyclohexanol, 4-methylcyclohexanol, or any combination thereof.

A glycol ether solvent may also be employed. An exemplary glycol ether solvent includes 1-methoxy-2-propanol, 2-methoxyethanol, 2-ethoxyethanol, 1-methoxy-2-butanol, ethylene glycol monoisopropyl ether, 1-ethoxy-2-propanol, 3-methoxy-1-butanol, ethylene glycol monoisobutyl ether, ethylene glycol mono-n-butyl ether, 3-methoxy-3-methylbutanol, ethylene glycol mono-tert-butyl ether, propylene glycol monomethyl ether (PGME), dipropylene glycol monomethyl ether (DPGME), or any combination thereof.

An exemplary glycol solvent includes ethylene glycol, propylene glycol, or any combination thereof.

An exemplary glycol ether ester solvent includes propylene glycol methyl ether acetate (PGMEA).

An exemplary ketone solvent includes acetone, methylethyl ketone, methyl iso-butyl ketone, cyclohexanone, isopropyl methyl ketone, 2-pentanone, 3-pentanone, 3-hexanone, diisopropyl ketone, 2-hexanone, cyclopentanone, 4-heptanone, iso-amyl methyl ketone, 3-heptanone, 2-heptanone, 4-methoxy-4-methyl-2-pentanone, 5-methyl-3-heptanone, 2-methylcyclohexanone, diisobutyl ketone, 5-methyl-2-octanone, 3-methylcyclohexanone, 2-cyclohexen-1-one, 4-methylcyclohexanone, cycloheptanone, 4-tert-butylcyclohexanone, isophorone, benzyl acetone, or any combination thereof.

An exemplary nitrile solvent includes acetonitrile, acrylonitrile, trichloroacetonitrile, propionitrile, pivalonitrile, isobutyronitrile, n-butyronitrile, methoxyacetonitrile, 2-methylbutyronitrile, isovaleronitrile, N-valeronitrile, n-capronitrile, 3-methoxypropionitrile, 3-ethoxypropionitrile, 3,3′-oxydipropionitrile, n-heptanenitrile, glycolonitrile, benzonitrile, ethylene cyanohydrin, succinonitrile, acetone cyanohydrin, 3-n-butoxypropionitrile, or any combination thereof.

An exemplary sulfoxide solvent includes dimethyl sulfoxide, di-n-butyl sulfoxide, tetramethylene sulfoxide, methyl phenyl sulfoxide, or any combinations thereof.

An exemplary amide solvent includes dimethyl formamide, dimethyl acetamide, acylamide, 2-acetamidoethanol, N,N-dimethyl-m-toluamide, trifluoroacetamide, N,N-dimethylacetamide, N,N-dimethyldodecanamide, epsilon-caprolactam, N,N-diethylacetamide, N-tert-butylformamide, formamide, pivalamide, N-butyramide, N,N-dimethylacetoacetamide, N-methyl formamide, N,N-diethylformamide, N-formylethylamine, acetamide, N,N-diisopropylformamide, 1-formylpiperidine, N-methylformanilide, or any combinations thereof.

A crown ether contemplated includes any one or more crown ethers that can function to assist in the reduction of the chloride content of an epoxy compound starting material as part of the combination being treated according to the invention. An exemplary crown ether includes benzo-15-crown-5; benzo-18-crown-6; 12-crown-4; 15-crown-5; 18-crown-6; cyclohexano-15-crown-5; 4′,4″(5″)-ditert-butyldibenzo-18-crown-6; 4′,4″(5″)-ditert-butyldicyclohexano-18-crown-6; dicyclohexano-18-crown-6; dicyclohexano-24-crown-8; 4′-aminobenzo-15-crown-5; 4′-aminobenzo-18-crown-6; 2-(aminomethyl)-15-crown-5; 2-(aminomethyl)-18-crown-6; 4′-amino-5′-nitrobenzo-15-crown-5; 1-aza-12-crown-4; 1-aza-15-crown-5; 1-aza-18-crown-6; benzo-12-crown-4; benzo-15-crown-5; benzo-18-crown-6; bis((benzo-15-crown-5)-15-ylmethyl)pimelate; 4-bromobenzo-18-crown-6; (+)-(18-crown-6)-2,3,11,12-tetra-carboxylic acid; dibenzo-18-crown-6; dibenzo-24-crown-8; dibenzo-30-crown-10; ar-ar′-di-tert-butyldibenzo-18-crown-6; 4′-formyl benzo-15-crown-5; 2-(hydroxymethyl)-12-crown-4; 2-(hydroxymethyl)-15-crown-5; 2-(hydroxymethyl)-18-crown-6; 4′-nitrobenzo-15-crown-5; poly-[(dibenzo-18-crown-6)-co-formaldehyde]; 1,1-dimethylsila-12-crown-4; 1,1-dimethylsila-14-crown-5; 1,1-dimethylsila-17-crown-5; cyclam; 1,4,10,13-tetrathia-7,16-diazacyclooctadecane; porphines; or any combination thereof.

In another embodiment, the liquid medium includes water. A conductive polymer complexed with a water-insoluble colloid-forming polymeric acid can be deposited over a substrate and used as a charge-transport layer.

Many different classes of liquid medium (e.g., halogenated solvents, hydrocarbon solvents, aromatic hydrocarbon solvents, water, etc.) are described above. Mixtures of more than one of the liquid medium from different classes may also be used.

The liquid composition may also include an inert material, such as a binder material, a filler material, or a combination thereof. With respect to the liquid composition, an inert material does not significantly affect the electronic, radiation emitting, or radiation responding properties of a layer that is formed by or receives at least a portion of the liquid composition.

It is to be appreciated that certain features of the invention which are for clarity, described above in the context of separate embodiments, may also be provided in combination in a single embodiment. Conversely, various features of the invention that are, for brevity described in the context of a single embodiment, may also be provided separately or in any subcombination. Further, reference to values stated in ranges include each and every value within that range.

What is claimed is:

1. An electronic device comprising:
a power bus;
a first conductive element;
a second conductive element;
a first organic active material; and
a first current limiting element wherein the first and second conductive elements and first organic active material form a first pixel, and the first current limiting element forms an electrical connection between the power bus and the first pixel.

2. The electronic device of claim 1 further comprising:
a second pixel; and
a second current limiting element wherein the second current limiting element forms an electrical connection between the power bus and the second pixel.

3. The electronic device of claim 1 wherein the first pixel is comprised of at least a first and a second sub-pixel.

4. The electronic device of claim 1 wherein the first conductive element is an anode.

5. The electronic device of claim 4 wherein the anode comprises a metal oxide.

6. The electronic device of claim 5 wherein the metal oxide is indium tin oxide.

7. The electronic device of claim 1 wherein the first current limiting element comprises an organic material.

8. The electronic device of claim 1 wherein the first current limiting element comprises an inorganic material.

9. The electronic device of claim 1 wherein the first current limiting element comprises a resistive material with resistivity of 100 to 10,000 ohms.

10. The electronic device of claim 9 wherein the resistive material has a serpentine pattern.

11. The electronic device of claim 10 wherein the electronic device is an organic light emitting diode display.

12. The electronic device of claim 10 wherein the electronic device is an organic light emitting diode lamp.

13. An organic light emitting diode device comprising:
a substrate;
a power bus;
a first conductive element;
a second conductive element;
a first organic active material; and
a first current limiting resistor wherein the first and second conductive elements and first organic active material form a first pixel, and the first current limiting resistor forms an electrical connection between the power bus and the first pixel.

14. The organic light emitting diode device of claim 13 wherein the first conductive element is an anode.

15. The organic light emitting diode device of claim 14 wherein the anode comprises a metal oxide.

16. The organic light emitting diode device of claim 15 wherein the metal oxide is indium tin oxide.

17. The organic light emitting diode device of claim 13 wherein the first current limiting resistor has a resistivity of 100 to 10,000 ohms.

18. The organic light emitting diode device of claim 17 wherein the resistive material has a serpentine pattern.

19. The organic light emitting diode device of claim 18 wherein the organic light emitting diode device is a display.

20. The organic light emitting diode device of claim 18 wherein the organic light emitting diode device is a lamp.
